(19) United States
(12) Patent Application Publication
(10) Pub. No.: US 2021/0287881 A1
(43) Pub. Date: Sep. 16, 2021

(54) METHODS AND APPARATUS FOR TUNING SEMICONDUCTOR PROCESSES

(71) Applicant: APPLIED MATERIALS, INC., Santa Clara, CA (US)

(72) Inventors: Timothy Joseph FRANKLIN, Campbell, CA (US); Carlaton WONG, Sunnyvale, CA (US); Reyn Tetsuro WAKABAYASHI, San Jose, CA (US); Daniel Sang BYUN, CAMPBELL, CA (US); Steven BABAYAN, Los Altos, CA (US)

(21) Appl. No.: 17/156,957

(22) Filed: Jan. 25, 2021

Related U.S. Application Data
(60) Provisional application No. 62/988,516, filed on Mar. 12, 2020.

(51) Int. Cl. H01J 37/32; H01L 21/687

(52) U.S. Cl. CPC H01J 37/32642; H01L 21/68735; H01J 37/32449; H01J 37/32724

(57) ABSTRACT

An apparatus for processing substrates that includes a process chamber with a process volume located above a substrate support assembly surrounded by an edge ring, an upper electrode located above the process volume and a conductive tuning ring surrounding the upper electrode and in electrical contact with the upper electrode. The conductive tuning ring has at least one gas port on a lower surface above the edge ring. The conductive tuning may also have at least one stepped portion on the lower surface that forms an extended bottom surface. In some embodiments, the extended bottom surface may slant radially inwardly or radially outwardly. In some embodiments, the extended bottom surface may have one or more radiused edges.

### CROSS-REFERENCE TO RELATED APPLICATIONS

This application claims benefit of U.S. provisional patent application Ser. No. 62/988,516, filed Mar. 12, 2020 which is herein incorporated by reference in its entirety.

### FIELD

Embodiments of the present principles generally relate to tuning rings used in semiconductor chambers for manufacturing semiconductor devices.

### BAC KGROU ND

Deposition and etch chambers used in the manufacturing of semiconductor devices need to produce consistent and uniform results for every substrate that is processed. Often plasma is used to enhance both deposition and etching of materials during the manufacturing process. The plasma can be generated through inductive coupling or capacitive coupling. In capacitively coupled plasma chambers, electrodes are used to create plasma in-between. Many factors affect the uniformity of the plasma which in turn affects the uniformity of the deposition on the substrates. The inventors have observed that the peripheral edge of the substrate is especially vulnerable to deposition nonuniformities.

Thus, the inventors have provided improved methods and apparatus that for increasing substrate edge deposition uniformity on substrates.

### SUMMARY

Methods and apparatus for increasing substrate edge deposition uniformity on substrates are provided herein.

In some embodiments, an apparatus for processing substrates may include a process chamber with a process volume located above a substrate support assembly surrounded by an edge ring, an upper electrode located above the process volume, and a conductive tuning ring surrounding the upper electrode and in electrical contact with the upper electrode, wherein the conductive tuning ring has at least one gas port on a lower surface above the edge ring.

In some embodiments, the apparatus may further include wherein the conductive tuning ring has at least one stepped portion on the lower surface that forms an extended bottom surface that is closer in proximity to the edge ring, wherein the extended bottom surface slants radially inwardly or slants radially outwardly, wherein at least one edge of the stepped portion is slanted upward, wherein at least one edge of the stepped portion is radiused, a heating source configured to control a temperature of the conductive tuning ring, wherein the at least one gas port includes one or more gas ports angled radially inwardly or one or more gas ports angled radially outwardly, and/or wherein the at least one gas port includes one or more gas ports angled tangentially.

In some embodiments, an apparatus for processing substrates may include a conductive tuning ring configured to surround an upper electrode and be in electrical contact with the upper electrode when installed in a process chamber, wherein the conductive tuning ring has at least one gas port on a lower surface configured to face an edge ring when installed in the process chamber.

In some embodiments, the apparatus may further include wherein the conductive tuning ring has at least one stepped portion on the lower surface that forms an extended bottom surface that is configured to be closer in proximity to the edge ring when installed in a process chamber, wherein the extended bottom surface slants radially inwardly or radially outwardly, wherein at least one edge of the stepped portion is radiused, wherein the conductive tuning ring and the upper electrode are formed as a unitary structure, wherein the at least one gas port includes one or more gas ports angled radially inwardly or one or more gas ports angled radially outwardly, and/or wherein the at least one gas port includes one or more gas ports angled tangentially.

In some embodiments, a method for depositing material on a substrate may include generating plasma in a process volume of a process chamber with the substrate on a substrate support assembly, flowing gas through at least one gas passage in a tuning ring that surrounds an upper electrode above the substrate support assembly, and depositing material onto the substrate.

In some embodiments, the method may further include adjusting at least one gas flow through the tuning ring to control a plasma sheath in the process volume, adjusting a rate of the at least one gas flow ora temperature of the tuning ring during deposition to control edge deposition uniformity of the substrate, adjusting a gas mixture of the at least on gas flow during deposition to control edge deposition of the substrate, and/or adjusting the at least one gas flow in conjunction with at least one second gas flow through the upper electrode to control deposition uniformity on the substrate.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross-sectional view of a process chamber for semiconductor processing in accordance with some embodiments of the present principles.

FIG. 2 depicts a cross-sectional view of an upper electrode assembly of a process chamber in accordance with some embodiments of the present principles.

FIG. 3 depicts a cross-sectional view of a tuning ring with radially inwardly directed gas passages in accordance with some embodiments of the present principles.

FIG. 4 depicts a cross-sectional view of a tuning ring with radially outwardly directed gas passages in accordance with some embodiments of the present principles.

FIG. 5 depicts a cross-sectional view of a tuning ring with both radially inwardly and radially outwardly directed gas passages in accordance with some embodiments of the present principles.

FIG. 6 depicts an isometric view of a top surface of a tuning ring with angled gas passages in accordance with some embodiments of the present principles.

FIG. 7 depicts a cross-sectional view of a profile of a tuning ring with a radially outwardly slanted stepped portion in accordance with some embodiments of the present principles.

FIG. 8 depicts a cross-sectional view of a profile of a tuning ring with a radially inwardly slanted stepped portion in accordance with some embodiments of the present principles.

FIG. 9 depicts a cross-sectional view of a profile of a tuning ring with a radially outwardly radiused stepped portion in accordance with some embodiments of the present principles.

FIG. 10 depicts a cross-sectional view of a profile of a tuning ring with a radially inwardly radiused stepped portion in accordance with some embodiments of the present principles.

FIG. 11 is a method of depositing material on a substrate in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus provide improved deposition uniformity in plasma process chambers. A tuning ring is placed around an upper electrode in a process chamber to facilitate in controlling plasma density during processing in order to produce more uniform depositions on a substrate. The tuning ring provides several parameters that allow tuning of the plasma near the periphery of the substrate. The tunable parameters give even more control over deposition uniformity. The tuning ring has a stepped portion with gas passages that enables finer control over gases used during processing to increase plasma and deposition uniformity, especially at the edges of the substrates. In some embodiments, the gas passages in the tuning ring are above an edge ring, enabling an ability to change the plasma sheath by bending the plasma sheath with gas flows having radial and axial components. The tuning ring allows better control of the edge deposition rate.

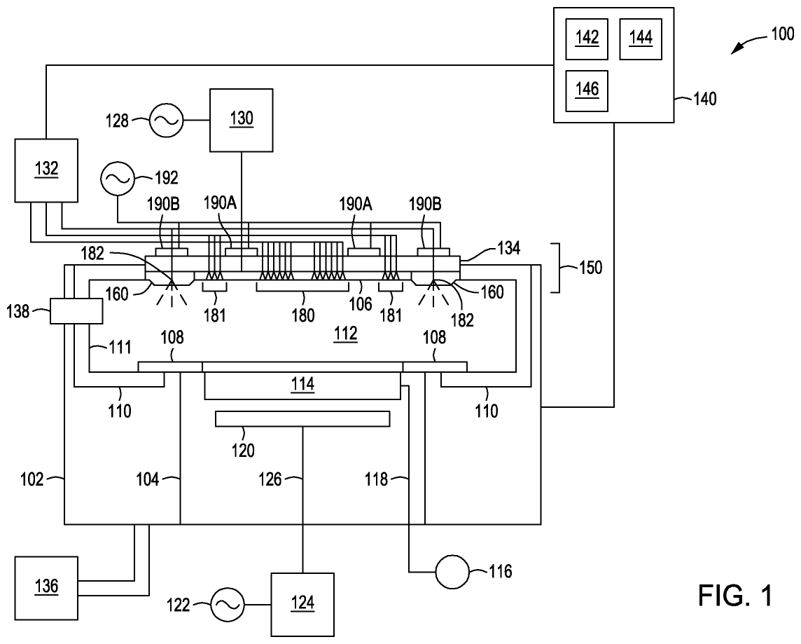

FIG. 1 depicts a cross-sectional view 100 of a process chamber 102 for semiconductor processing in accordance with some embodiments. The process chamber 102 includes a substrate support assembly 104 and an upper electrode assembly 150. The upper electrode assembly 150 includes an upper electrode 106 and a tuning ring 160 that are attached to a backing plate 134. The upper electrode assembly 150 may also include one or more heating sources 190A, 190B that are electrically connected to an AC heater power source 192. In some embodiments, the heating sources 190A, 190B may include resistive type electrical heaters (shown in FIG. 1) and/or fluid exchange type heaters (not shown). In some embodiments, the upper electrode 106 may have one or more sets of heating sources 190A and/or temperatures sensors to provide temperature control in one or more zones of the upper electrode 106. In some embodiments, the tuning ring 160 may have one or more heating source 190B and/or temperature sensors to permit separate temperature control of the tuning ring 160 from the upper electrode 106. The separate temperature control of the tuning ring 160 allows for an additional tuning parameter during processing of a substrate and the like. In some embodiments, the temperature control may be provided by a controller 140 discussed in detail below. In some embodiments, the heating sources 190A, 190B may have one or more resistive heating elements or liquid-based heating elements and the like. The upper electrode 106 and the tuning ring 160 are electrically connected. In some embodiments, the upper electrode 106 and the tuning ring 160 are formed as a single unitary piece. An edge ring 108 interfaces with a conductance liner 110 and the substrate support assembly 104. The upper electrode 106, the conductance liner 110, and the edge ring 108 help to define a process volume 112. The substrate support assembly 104 includes an electrostatic chuck (ESC) assembly 114 that is electrically connected via a first conductor 118 to a DC power supply 116. The DC power supply 116 provides DC voltage to the ESC assembly 114 to electrostatically clamp substrates to the substrate support assembly 104. A slit valve 138 in a vertical wall 111 of the conductance liner 110 provides access to the process volume 112. Substrates are moved through the slit valve 138 and placed on the ESC assembly 114 for processing or removed from the ESC assembly 114 after processing.

The substrate support assembly 104 also includes a lower electrode 120 that is electrically connected via a second conductor 126 to an RF bias power supply 122 via an RF bias matching network 124. The upper electrode 106 is electrically connected to an RF power supply 128 via an RF matching network 130. The upper electrode 106 may also include one or more zones of gas passages 180, 181 that are fluidly connected to a gas supply 132. The tuning ring 160 has one or more gas passages 182 connected to the gas supply 132 as well. In some embodiments, three zones may be used to provide different gas controls over the center, middle, and edge of the substrate. The center and middle zones are provided by gas passages in the upper electrode 106 and the edge zone is provided by the tuning ring 160. In some embodiments, the gases may include one or more noble gases and/or one or more process gases. In some embodiments, the gases may be specific to a cleaning process. In some embodiments, the upper electrode 106 and the tuning ring 160 may be connected to the same gas supply or different gas supplies. A vacuum pump 136 assists in removing byproducts and/or gases from the process chamber 102.

A controller 140 controls the operation of the process chamber 102 using a direct control or indirect control via other computers (or controllers) associated with the process chamber 102. In operation, the controller 140 enables data collection and feedback from the process chamber 102 and peripheral systems to optimize performance of the process chamber 102. The controller 140 generally includes a Central Processing Unit (CPU) 142, a memory 144, and a support circuit 146. The CPU 142 may be any form of a general-purpose computer processor that can be used in an industrial setting. The support circuit 146 is conventionally coupled to the CPU 142 and may comprise a cache, clock circuits, input/output subsystems, power supplies, and the like. Software routines, such as a method as described above may be stored in the memory 144 and, when executed by the CPU 142, transform the CPU 142 into a specific purpose computer (controller 140). The software routines may also be stored and/or executed by a second controller (not shown) that is located remotely from the process chamber 102.

The memory 144 is in the form of computer-readable storage media that contains instructions, when executed by the CPU 142, to facilitate the operation of the semiconductor processes and equipment. The instructions in the memory 144 are in the form of a program product such as a program that implements the method of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

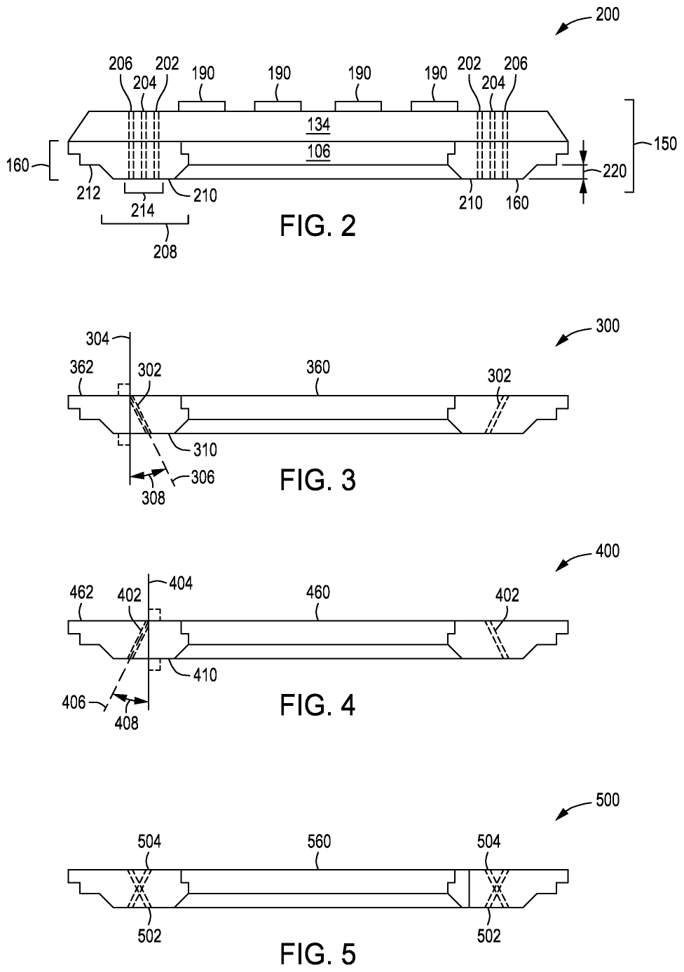

FIG. 2 depicts a cross-sectional view 200 of an upper electrode assembly 150 of a process chamber in accordance with some embodiments. The tuning ring 160 has a stepped portion 208 and a non-stepped portion 212. The stepped portion 208 and the non-stepped portion 212 may be formed as a monolithic piece or may be formed as two separate pieces. A face 210 of the stepped portion 208 is closer to an edge ring when installed in a process chamber. The proximity of the face 210 to the edge ring during plasma formation causes increased conductance and increased plasma density near the periphery of a substrate on a substrate assembly. A height 220 of the stepped portion 208 may be adjusted based on process parameters to enhance deposition uniformity at the edge of the substrate. The stepped portion 208 has openings 214 for gas emission. The inventor has found that the gas velocities and gas passage orientations may have impacts on the life expectancy of an edge ring, such as a quartz material edge ring due to an increase in erosion of the edge ring caused by the gas. For example, more gas passages may be used to reach a certain flow volume for a process rather than increasing the flow rate of less gas passages in order to reduce the eroding effect of the gases.

The tuning ring 160, in this example, illustrates one or more concentric rings of gas passages 202-206 that go through the backing plate 134 and the tuning ring 160. In some embodiments, the gas passages 202-206 may include any pattern that facilitates in tuning gases during processes to enhance deposition uniformity. The one or more concentric rings of gas passages 202-206 are shown perpendicular in orientation with the face 210 of the stepped portion 208 of the tuning ring 160. The one or more concentric rings of gas passages 202-206 includes an inner ring of gas passages 202, an intermediate ring of gas passages 204, and an outer ring of gas passages 206. In some embodiments, the one or more concentric rings of gas passages 202-206 may flow the same gas or different gases. In some embodiments, the one or more concentric rings of gas passages 202-206 may have one or more individual gas passages with different orientations that are not perpendicular to the face 210 of the stepped portion 208 (discussed in more detail below).

FIG. 3 depicts a cross-sectional view 300 of a tuning ring 360 with at least one radially inwardly directed gas passage 302 in accordance with some embodiments. The at least one radially inwardly directed gas passage 302 has an angle 308 measured from a first axis 304 that is perpendicular to a stepped portion 310 and/or a back surface 362 of the tuning ring 360 to a second axis 306 drawn through a center of the radially inwardly directed gas passage 302. In some embodiments, the stepped portion 310 may not be a parallel surface (see below). The inventor has found that if the angle 308 is less than 90 degrees, the plasma formed in the process volume 112 of the process chamber 102 is less likely to discharge into the gas passage, extending the life of the tuning ring 360. FIG. 4 depicts a cross-sectional view 400 of a tuning ring 460 with at least one radially outwardly directed gas passage 402 in accordance with some embodiments. The at least one radially inwardly directed gas passage 402 has an angle 408 measured from a first axis 404 that is perpendicular to a stepped portion 410 and/or a back surface 462 of the tuning ring 460 to a second axis 406 drawn through a center of the radially outwardly directed gas passage 402. In some embodiments, the stepped portion 410 may not be a parallel surface (see below). The inventor has found that if the angle 408 is less than 90 degrees, the plasma formed in the process volume 112 of the process chamber 102 is less likely to discharge into the gas passage, extending the life of the tuning ring 460. FIG. 5 depicts a cross-sectional view 500 of a tuning ring 560 with at least one radially inwardly directed gas passage 502 and at least one radially outwardly directed gas passage 504 in accordance with some embodiments.

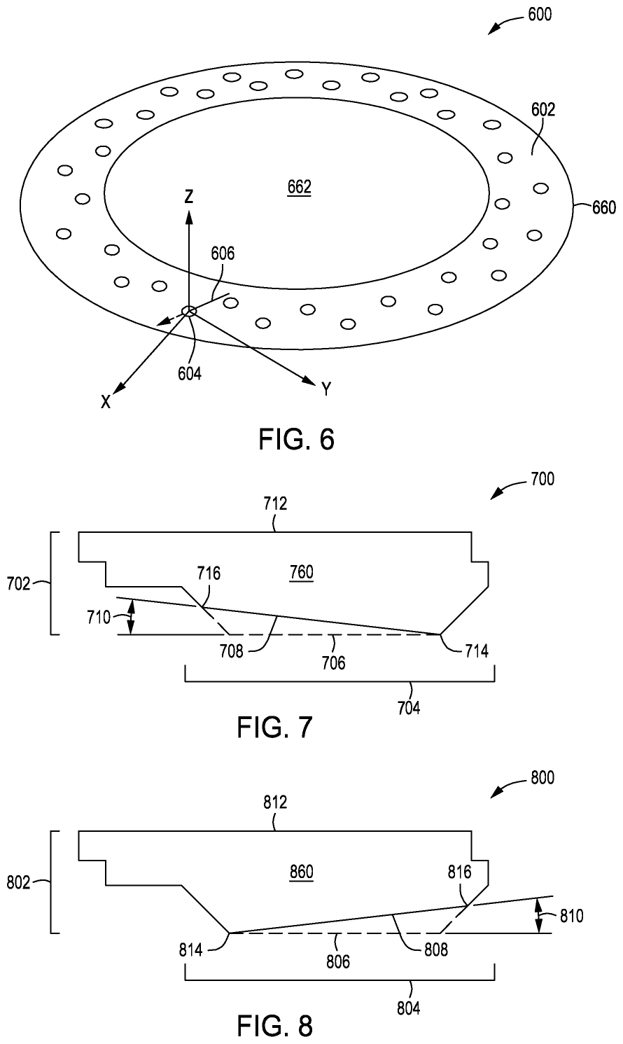

FIG. 6 depicts an isometric view 600 of a top surface 602 of a tuning ring 660 with at least one angled gas passage 604 in accordance with some embodiments. In some embodiments, the tuning ring 660 may be made separately from an upper electrode 662 or as a unitary structure combined with the upper electrode 662. The angled gas passage 604 may have an angle with a vector 606 that can be mapped into three-dimensional space. As discussed above, the angled gas passage 604 can have a radially inwardly or radially outwardly angle. The angled gas passage 604 may also have a tangential component to the radially inwardly or radially outwardly angle. In some embodiments, the vectors of the gas passages may form a clockwise and/or counterclockwise spiral. In some embodiments, the gas flow from the gas passages may produce a ‘gas curtain’ that facilitates to aid in deposition uniformity and also to control deposition particulates.

FIG. 7 depicts a cross-sectional view 700 of a profile 702 of a tuning ring 760 with a stepped portion 704 in accordance with some embodiments. Rather than a face 706 of the stepped portion 704 being parallel to a top surface 712 of the stepped portion 704 or a top surface of an edge ring (not shown) when installed in a process chamber, in some embodiments, a radially outwardly slanted face 708 is used instead. The radially outwardly slant angle 710 may be from greater than zero to approximately 30 degrees. In some embodiments, the tuning ring 760 is installed in a process chamber directly above the edge ring. The radially outwardly slanted face 708 creates a higher density plasma at a slant high point 714 which is closer to an outer periphery edge of a substrate than at a slant low point 716 which is at a point farther away from the outer periphery edge of the substrate. Slanting the face 706 of the tuning ring 760 enables another parameter than can be used during process to facilitate tuning the uniformity of the plasma and the uniformity of the deposition and/or tuning gas flow through the tuning ring 760.

FIG. 8 depicts a cross-sectional view 800 of a profile 802 of a tuning ring 860 with a stepped portion 804 in accordance with some embodiments. Rather than a face 806 of the stepped portion 804 being parallel to a top surface 812 of the tuning ring 860 or a top surface of an edge ring (not shown) when installed in a process chamber, in some embodiments, a radially inwardly slanted face 808 is used instead. The radially inwardly slant angle 810 may be from greater than zero to approximately 30 degrees. The radially inwardly slanted face 808 creates a lower density plasma at a slant low point 816 which is closest to an outer periphery edge of a substrate than at a slant high point 814 which is at a point farthest away from the outer periphery edge of the substrate. Slanting the face 806 of the tuning ring 860 enables another parameter than can be used during process to facilitate tuning the uniformity of the plasma and the uniformity of the deposition and/or tuning gas flow through the tuning ring 860.

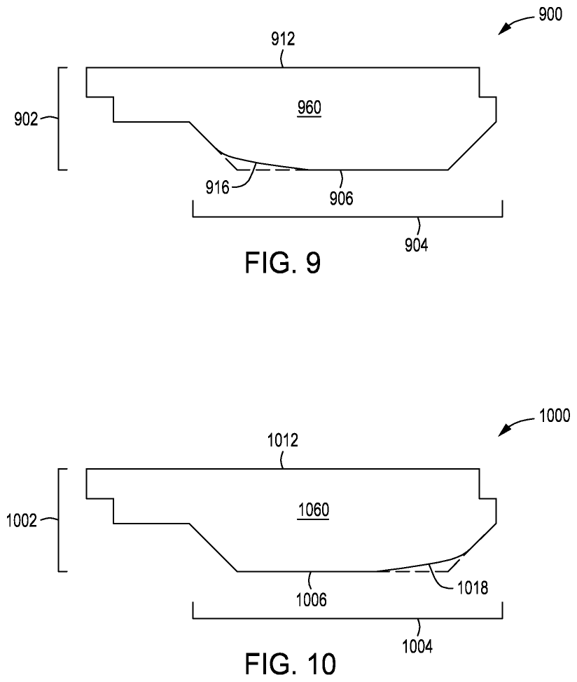

FIG. 9 depicts a cross-sectional view 900 of a profile 902 of a tuning ring 960 with a radially outwardly radiused stepped portion 916 in accordance with some embodiments. The radially outwardly radiused stepped portion 916 allows for finer tuning of the plasma density furthest away from the outer periphery edge of substrate. A face 906 of the stepped portion 904 is generally parallel to a top surface 912 of the tuning ring 960. By radiusing the edge of the face 906 of the stepped portion 904, the density and shape of the plasma can be finely tuned to increase deposition uniformity on a substrate. FIG. 10 depicts a cross-sectional view 1000 of a profile 1002 of a tuning ring 1060 with a radially inwardly radiused stepped portion 1018 in accordance with some embodiments. The radially inwardly radiused stepped portion 1018 allows for finer tuning of the plasma density closest to the outer periphery edge of substrate. A face 1006 of the stepped portion 1004 is generally parallel to a top surface 1012 of the tuning ring 1060. By radiusing the edge of the stepped portion 1004, the density and shape of the plasma can be finely tuned to increase deposition uniformity on a substrate.

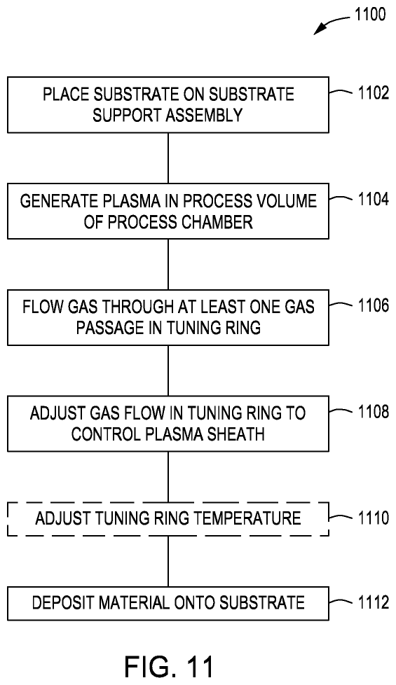

FIG. 11 is a method 1100 of depositing material on a substrate in accordance with some embodiments. In block 1102, a substrate is placed on a substrate support assembly in a plasma enhanced deposition chamber. In block 1104, plasma is generated in a process volume of the plasma enhanced deposition chamber. In block 1106, gas is flowed through at least one gas passage in a tuning ring that surrounds an upper electrode in the plasma enhanced deposition chamber. In block 1108, the gas flow through the tuning is adjusted to control the plasma sheath. The gas flow enables process control or tuning especially at the peripheral edge of the substrate. The gas flow volume or rate may be constant during the process and/or may be varied or ramped up or down during the process. In some embodiments, different gases and/or different mixtures of gases may be used during a process. In some embodiments, the gas parameters may be determined in conjunction with gas parameters for gas passages in an upper electrode as well to control overall substrate deposition uniformity. In optional block 1110, a temperature of the tuning ring is adjusted. The adjusting of the temperature of the tuning ring provides an additional tuning parameter to adjust substrate deposition uniformity during processing. In block 1112, material is deposited onto the substrate with high uniformity.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. An apparatus for processing substrates, comprising:
a process chamber with a process volume located above a substrate support assembly surrounded by an edge ring;
an upper electrode located above the process volume; and
a conductive tuning ring surrounding the upper electrode and in electrical contact with the upper electrode, wherein the conductive tuning ring has at least one gas port on a lower surface above the edge ring.

2. The apparatus of claim 1, wherein the conductive tuning ring has at least one stepped portion on the lower surface that forms an extended bottom surface that is closer in proximity to the edge ring.

3. The apparatus of claim 2, wherein the extended bottom surface slants radially inwardly or slants radially outwardly.

4. The apparatus of claim 2, wherein at least one edge of the stepped portion is slanted upward.

5. The apparatus of claim 2, wherein at least one edge of the stepped portion is radiused.

6. The apparatus of claim 1, further comprising a heating source configured to control a temperature of the conductive tuning ring.

7. The apparatus of claim 1, wherein the at least one gas port includes one or more gas ports angled radially inwardly or one or more gas ports angled radially outwardly.

8. The apparatus of claim 1, wherein the at least one gas port includes one or more gas ports angled tangentially.

9. An apparatus for processing substrates, comprising.
a conductive tuning ring configured to surround an upper electrode and be in electrical contact with the upper electrode when installed in a process chamber, wherein the conductive tuning ring has at least one gas port on a lower surface configured to face an edge ring when installed in the process chamber.

10. The apparatus of claim 9, wherein the conductive tuning ring has at least one stepped portion on the lower surface that forms an extended bottom surface that is configured to be closer in proximity to the edge ring when installed in a process chamber.

11. The apparatus of claim 10, wherein the extended bottom surface slants radially inwardly or radially outwardly.

12. The apparatus of claim 10, wherein at least one edge of he stepped portion is radiused.

13. The apparatus of claim 9, wherein the conductive tuning ring and the upper electrode are formed as a unitary structure.

14. The apparatus of claim 9, wherein the at least one gas port includes one or more gas ports angled radially inwardly or one or more gas ports angled radially outwardly.

15. The apparatus of claim 9, wherein the at east one gas port includes one or more gas ports angled tangentially.

16. A method for depositing material on a substrate, comprising:
generating plasma in a process volume of a process chamber with he substrate on a substrate support assembly;
flowing gas through at least one gas passage in a tuning ring that surrounds an upper electrode above the substrate support assembly; and
depositing material onto the substrate.

17. The method of claim 16, further comprising:
adjusting at least one gas flow through the tuning ring to control a plasma sheath in the process volume,

18. The method of claim 6, further comprising:
adjusting a rate of at least one gas flow or a temperature of the tuning g during deposition to control edge deposition uniformity of the substrate.

19. The method of claim 16, further comprising:
adjusting a gas mixture of the at least on gas flow during deposition to control edge deposition of the substrate.

20. The method of claim 16, further comprising:
adjusting at least one gas flow in conjunction with at least one second gas flow through the upper electrode to control deposition uniformity on the substrate.
